(19) United States
(12) Patent Application Publication
(10) Pub. No.: US 2021/0045244 A1
(43) Pub. Date: Feb. 11, 2021

(54) MULTIPLE CIRCUIT BOARDS WITH HIGH-DENSITY COMPRESSION INTERCONNECT

(71) Applicant: Samtec, Inc., New Albany, IN (US)

(72) Inventors: Norman S. MCMORROW, New Albany, IN (US); Keith R. GUETIG, New Albany, IN (US); Jignesh H. SHAH, New Albany, IN (US)

(21) Appl. No.: 16/965,135

(22) PCT Filed: Mar. 15, 2019
(86) PCT No.: PCT/US2019/070003

§ 371 Date: Jul. 27, 2020

Related U.S. Application Data
(60) Provisional application No. 62/644,043, filed on Mar. 16, 2018.
(60) Provisional application No. 62/666,915, filed on May 4, 2018.

(51) Int. Cl. H05K 1/14; H05K 1/11

(52) U.S. Cl. CPC H05K 1/144; H05K 2201/10189; H05K 2201/041; H05K 1/115

(57) ABSTRACT

A printed circuit board (PCB) assembly includes a first PCB, a high-speed PCB, and a high-speed interconnect electrically and physically connecting the first PCB and the high-speed PCB.

### CROSS REFERENCE TO RELATED APPLICATIONS

This application claims the benefit of U.S. Patent Application No. 62/644,043 filed on Mar. 16, 2018 and U.S. Patent Application No. 62/666,915 filed on May 4, 2018. The entire contents of each application are hereby incorporated by reference.

### BACKGROUND OF THE INVENTION

### 1. Field of the Invention

The present invention relates to an architecture and a method to electrically and physically connect multiple circuit boards together. More specifically, the present invention relates to connecting a conventional printed circuit board to a high-speed printed circuit board with a high-density compression interconnect.

### 2. Description of the Related Art

A printed circuit board (PCB) is a mechanical substrate that supports and electrically connects electronic components. PCB technology provides a way to reduce the size, weight, and cost of circuitry over previously available point-to-point wiring methods. A PCB uses conductive tracks, traces, pads, vias, through holes, and other features that are plated or etched from one or more conductive sheets that are laminated onto and between sheet layers of non-conductive or insulating substrate material. PCBs can be single-sided, with a conductive layer only on one side of the non-conductive substrate; double-sided, with conductive layers on both sides of the non-conductive substrate; or multilayered with alternating layers of conductive and non-conductive layers that are laminated or bonded together.

Connectors and electrical components can be soldered onto a PCB to establish electrical and mechanical connections between the connectors and electrical components and the PCB. Pins, legs, or terminals of components can be placed into conductive holes in the PCB (through-holes) or aligned with conductive pads defined on an exposed surface of the PCB (surface mount technology (SMT)), and then soldered in place. Soldering provides electrical and mechanical connections between the component and the PCB.

A typical PCB consists of a layer of copper, copper foil, or other conductive metal laminated to a flat sheet of insulating material that forms a substrate. The metal layer is then patterned to define separate conducting traces, connection pads, and vias to pass connections between layers of copper, and features such as solid conductive areas that provide shielding, grounding, or other purposes. The conductive traces are insulated from each other by air and the substrate material.

A PCB can have multiple metal layers. In multilayer PCBs, the layers of material are laminated together in an alternating sandwich of metal and insulating substrate, and any internal vias (that will not extend to both outer surfaces of the finished multilayer board) are plated-through, before the layers are laminated together. The inner metal layers are protected by the adjacent substrate layers. The metal thickness can be optimized in view of current carrying requirements and heat dissipation needs. There can be many alternating layers of conductive and insulating materials.

FR-4 is a glass epoxy that is commonly used as the insulating substrate. FR-4 is a glass-reinforced epoxy laminate material that includes woven fiberglass cloth with an epoxy resin binder that is flame resistant. FR-4 has been found to provide a cost-effective material that balances required thermal, electrical, chemical, and mechanical properties of most PCBs.

Although FR-4 is a versatile PCB substrate material, it does not satisfy all circuit performance needs. Alternate substrate materials and constructions are available to meet certain needs, including increased dielectric constant, reduced moisture absorption, and higher bonding strength. As these needs and corresponding materials are less common, PCB materials used to provide these specialty requirements are more expensive.

For example, the dielectric constant of a material is an important parameter in view of signal integrity (SI) and impedance in PCB circuit design. SI and impedance are critical factors in high-frequency electrical performance. The dielectric constant of a material varies with frequency and generally decreases as frequency increases. As the dielectric constant determines the signal propagation speed, frequency dependence can introduce phase distortion in wideband applications. Also, the impedance of transmission lines decreases with frequency; therefore, faster signals reflect more than slower ones. Therefore, materials with a flat dielectric constant over a wide frequency range are more desirable in high-frequency applications. As a result, a PCB with a FR-4 substrate will not meet the needs in many high-speed applications.

FIG. 1 shows a known architecture with one PCB 100 that is multilayered and that routes power, control signals, and high-speed data signals. Control signals can control the integrated circuit (IC) 101. PCB 100 and IC 101 can be included in an IC or die package. For example, if the integrated circuit is an application-specific IC (ASIC), then the control signals can include signals to setup operation of the ASIC. High speed is defined to be any digital signaling technique with a baud rate, i.e., a signaling symbol rate for NRZ, PAM4, PAM8, etc., greater than or equal to 10 GHz, i.e., higher than 10 gigabaud. For example, the PCB 100 can include 24-36 layers and can be 3.5 mm-4.0 mm thick with vias 103 used to transport (i.e., transmit and receive) high-speed signals. FIG. 1 shows the PCB 100 with components on both sides. The top side of the PCB 100 can include the IC 101. The IC 101 can be any silicon chip, including, for example, an ASIC, a switch IC, a field-programmable gate array (FPGA), or other components. The bottom side of the PCB 100 can include bypass capacitors 104 that are used with the power supply or other components. FIG. 1 also shows that high-speed connectors, which can be copper or optical, can be attached to the top and/or the bottom sides of the PCB 100. The PCB 100 transports high-speed signals between the IC 101 and the high-speed connectors. The high-speed signals can be transported through traces on the top and bottom surfaces of the PCB 100 and through vias 103 that connect the top and bottom sides of the PCB 100. The vias 103 can be high-speed vias. High-speed vias 103 have a specific pitch and number of grounds (and possibly other internal metal patterns not shown in the drawings) that are designed to maximize bandwidth and to minimize reflection. High-speed vias 103 can transport high-speed signals at more than 10 gigabaud, where signals with speeds less than 10 gigabaud are typically power and control signals. Examples of high-speed vias 103 are shown in U.S. Application No. 61/531,714, Ser. Nos. 13/607,281, 13/607,298, and 13/607,338. The entire contents of each of these applications are hereby incorporated by reference. Because of the high frequency of the high-speed signals, the PCB 100 needs to be made of high-performance materials, which are expensive. Because SI is degraded when signals are transported through traces on or in a PCB 100, it is known to locate the high-speed connectors as close to the IC 101 as possible to reduce SI degradation. But the path length is not zero, and the SI of the signals is still degraded, with higher frequencies being degraded more than lower frequencies.

Consequently, the entire PCB 100 must be made with high-performance materials and can include additional isolating ground planes to shield sensitive high-speed data signals from slower power and control signals that are less susceptible to interference. This results in a more complicated and expensive PCB 100 with compromises in the electrical design.

### SUMMARY OF THE INVENTION

To overcome the problems described above, preferred embodiments of the present invention provide an assembly and a method that provide a PCB architecture that allows separation of the low-speed power/control signals from the high-speed data signals. More specifically, the low-speed power/control signals are routed on a lower-cost PCB constructed of FR-4 or similar material, the high-speed signals are routed on a high-speed PCB using engineered PCB material, and a high-density compression interconnect is used to connect the two PCBs together, which allows a series of PCBs to be connected together as needed to meet design requirements and reduce or minimize cost.

According to a preferred embodiment of the present invention, a printed circuit board (PCB) assembly includes a first PCB, a high-speed PCB, and a high-speed interconnect electrically and physically connecting the first PCB and the high-speed PCB.

The first PCB preferably transports power and control signals. The first PCB preferably includes high-speed vias that transport high-speed signals between the first PCB and the high-speed PCB. Preferably, the first PCB includes an integrated circuit (IC), and the high-speed vias transport the high-speed signals between the IC and the high-speed PCB. The PCB assembly further preferably includes a die package that includes the first PCB and an integrated circuit (IC).

The high-speed PCB preferably transports high-speed data signals. The PCB assembly further preferably includes a high-speed connector connected to the high-speed PCB. The high-speed connector preferably is either a copper connector or an electrical/optical assembly with an optical connector. The high-speed PCB preferably includes engineered PCB material. The first PCB preferably includes FR-4.

The high-speed interconnect preferably is a compression interconnect. The high-speed interconnect preferably includes compression contacts.

According to a preferred embodiment of the present invention, a high-speed printed circuit board (PCB) assembly includes a high-speed PCB that includes engineered PCB material and a high-speed interconnect that is electrically and physically connected to the high-speed PCB and that is mateable with another PCB.

The high-speed PCB preferably transports high-speed data signals. The high-speed PCB preferably includes a high-speed connector. The high-speed connector preferably is either a copper connector or an electrical/optical assembly with an optical connector. The high-speed interconnect preferably is a compression interconnect. The high-speed interconnect preferably includes compression contacts.

According to a preferred embodiment of the present invention, a transmission apparatus includes a die package removably connected to a high-speed printed circuit board and a high-speed interconnect positioned between the die package and the high-speed printed circuit board. The die package preferably includes an FR-4 substrate.

According to a preferred embodiment of the present invention, a cable assembly includes a plurality of power-and-control PCBs each interconnected to a common power and control PCB by flexible circuits, coaxial cables, or twin axial cables and optional dies positioned on the power-and-control PCBs.

According to a preferred embodiment of the present invention, a cable assembly can include a plurality of high speed PCBs interconnected to a common high speed PCB by flexible circuits, coaxial cables, or twin axial cables.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 shows a side view of a known multilayer PCB.

FIG. 2 shows a side view of an exemplary dual PCB architecture according to a preferred embodiment of the present invention.

FIG. 3 shows an exploded view of a dual PCB architecture according to a preferred embodiment of the present invention.

FIGS. 4 and 5 are respective top and bottom plan views of exemplary high-speed compression interconnects according to a preferred embodiment of the present invention.

FIG. 6 is a view of five PCBs connected to one PCB using high-speed compression interconnects according to a preferred embodiment of the present invention.

FIG. 7 is a cross-sectional view of the dual PCB architecture of FIG. 3.

FIG. 8 is a cross-section view of a compression connector with compression contacts on two opposing sides.

### DETAILED DESCRIPTION OF PREFERRED EMBODIMENTS

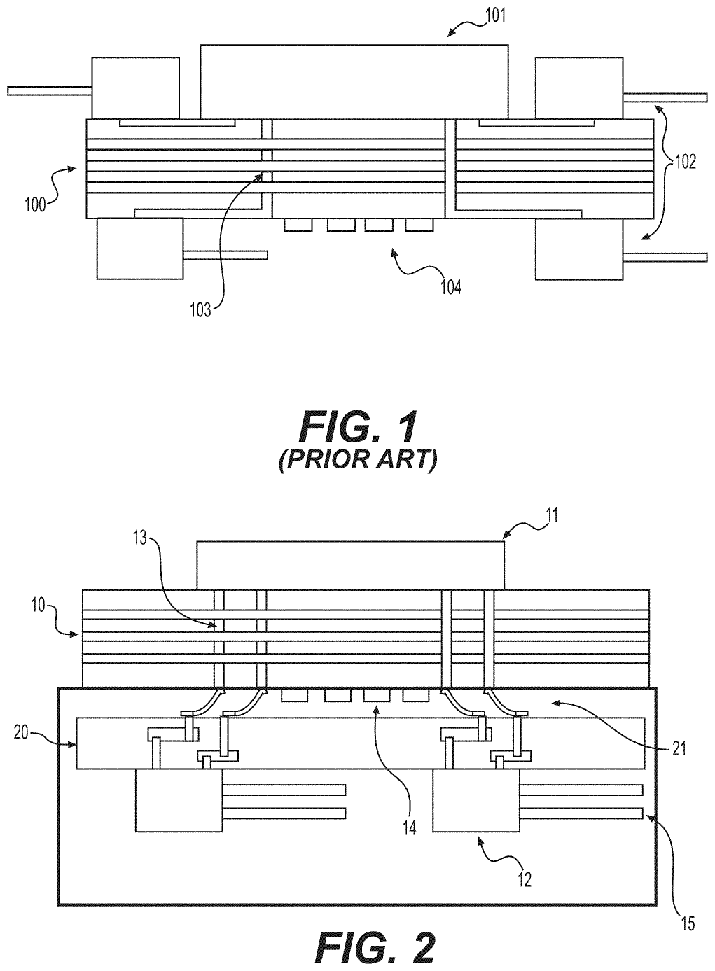

FIG. 2 shows a preferred embodiment of the present invention that includes two PCBs 10, 20 that are connected together. FIG. 2 shows one power or control, or one power-and-control PCB 10 and one high-speed PCB 20. The power-and-control PCB 10 that routes power and control signals is a simpler and lower cost PCB, for example, and can be constructed of layers of FR-4 substrate material, such as 8-10 layers, or other similar low-cost PCB material, that is in total about 1 mm to about 2 mm thick. As shown in FIG. 2, the top side of the power-and-control PCB 10 can include an integrated circuit (IC) 11 or other components, and the bottom side can include bypass capacitors 14 that can be used with the power supply or other components. PCB 10 and IC 11 can be included in an IC or die package. The IC 11 can be any silicon chip, including, for example, an ASIC or switch IC. The power-and-control PCB 10 includes signal vias 13 that transport signals, such as differential signals, between the IC 11 and the high-speed PCB 20. The high-speed signals between the IC 11 and the high-speed PCB 20 can be transported only using the vertical vias 13, without using any of the horizontal traces in FIG. 1 that extend perpendicularly with respect to the vias 103, adjacent to two opposed major, parallel surfaces of the power-and-control PCB 10. With regard to FIG. 2, vertical is defined herein as having a quantity and direction vector that extends through the thickness of the low-cost PCB material. Stated another way, vertical means that the vias extend in a direction between the two opposed major, parallel sides or surfaces of the low-cost PCB material.

The high-speed PCB 20 shown in FIG. 2, for example, routes high-speed data signals and can be constructed of layers of engineered PCB material, such as 8-10 layers. A high-speed PCB 20 includes a PCB with a data transfer rate greater than or equal to 15 Gbits/sec but less than or equal to 114 Gbits/sec with less than 1% or 2% or 3% or 4% multi-active, worst-case, asynchronous, time domain cross-talk; a data transfer rate greater than or equal to 20 Gbits/sec but less than or equal to 114 Gbits/sec with less than 1% or 2% or 3% or 4% multi-active, worst-case, asynchronous, time domain cross-talk; a data transfer rate greater than or equal to 25 Gbits/sec but less than or equal to 114 Gbits/sec with less than 1% or 2% or 3% or 4% multi-active, worst-case, asynchronous, time domain cross-talk; a data transfer rate greater than or equal to 40 Gbits/sec but less than or equal to 114 Gbits/sec or 240 Gbits/sec with less than 1% or 2% or 3% or 4% multi-active, worst-case, asynchronous, time domain cross-talk; a data transfer rate greater than or equal to 60 Gbits/sec but less than or equal to 114 Gbits/sec or 240 Gbits/sec with less than 1% or 2% or 3% or 4% multi-active, worst-case, asynchronous, time domain cross-talk; a data transfer rate greater than or equal to 100 Gbits/sec but less than or equal to 240 Gbits/sec with less than 1% or 2% or 3% or 4% multi-active, worst-case, asynchronous, time domain cross-talk; or a data transfer rate greater than or equal to 112 Gbits/sec but less than or equal to 240 Gbits/sec with less than 1% or 2% or 3% or 4% multi-active, worst-case, asynchronous, time domain cross-talk. Engineered PCB materials can include materials such as ceramic, PTFE, polyimide, pyralux, metal core, cyanate ester, polyphenylene oxide, etc. with one or more of the following properties: low loss, low copper surface roughness, and selective fiberglass weave. The engineered PCB material can include non-fiberglass materials. The engineered PCB materials are chosen based on their particular properties or high-speed signaling capabilities and may include matched dielectric constants between resin and woven material and matched coefficient of thermal expansion between engineered PCB materials and a tightly woven material to reduce air gaps in the weave.

The high-speed PCB 20 can define a relief cavity (not shown) in which the bypass capacitors 14 can be located when the high-speed PCB 20 is attached to the power-and-control PCB 10.

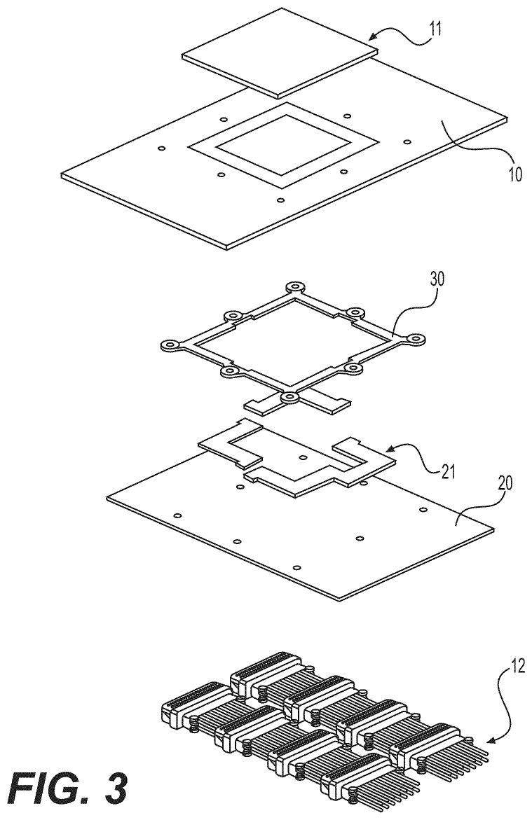

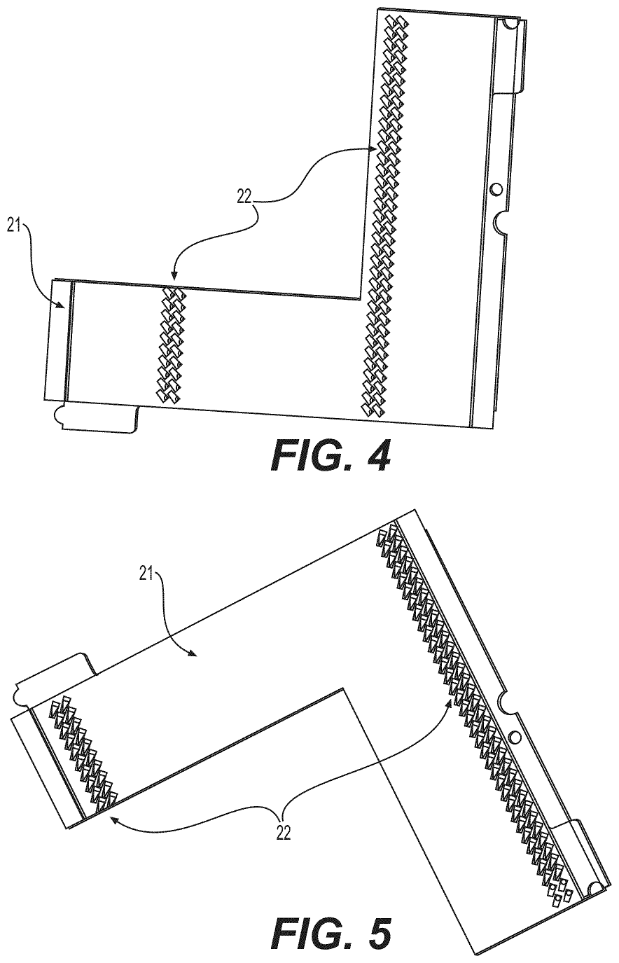

FIG. 2 shows that a connector, bounded by the rectangle with thick lines in FIG. 2, physically and electrically connects to the power-and-control PCB 10 or die package. The connector can include a high-speed connector 12 that can be mounted on one side of the high-speed PCB 20 and that high-speed interconnects 21 can connect the power-and-control PCB 10 to the high-speed PCB 20. The high-speed interconnects 21 can include a housing or substrate, as shown in FIGS. 4 and 5 or cannot include a housing or substrate, i.e., contacts directly attached to the high-speed PCB 20 as shown in FIG. 2. FIG. 2 shows two high-speed connectors 12, and FIG. 3 shows eight high-speed connectors 12, but any number of high-speed connectors 12 are possible. The high-speed connector 12 can either be a copper connector or an optical connector. For copper connectors, the high-speed connectors can be compression, LGA-LGA, SMT to LGA, SMT to SMT, or some other acceptable connection interface. Alternatively, the connector can only include the high-speed PCB 20 and the high-speed cable connectors 12.

As shown in FIG. 2, cables 15 extend from the high-speed connectors 12. The cables 15 can include copper wires or optical fibers. If copper cable is used, then it can be a single wire, a coaxial cable, or a twin-axial cable. If optical fibers are used, then an active optical cable (AOC) can be used. An AOC includes a transceiver that is connected to the high-speed PCB 20. The transceiver can include active electronics and optical components. The active electronics and optical components can convert electrical signals into optical signals and/or convert optical signals into electrical signals. An example of a transceiver that can be used is a FireFly™ optical transceiver, from Samtec, Inc. of New Albany, Ind. The portion of the cables 15 connected to the high-speed connectors 12 extend from the high-speed connectors 12 in a direction parallel or substantially parallel within manufacturing tolerances to a facing surface of the high-speed PCB 20. Because the cables 15 extend parallel from the high-speed connectors 12, more space on the high-speed PCB 20 is needed to mate with the high-speed connectors 12, decreasing the density of the data signals. Instead of extending parallel, the portions of the cables 15 connected to the high-speed connectors 12 could extend at any angle from the high-speed connectors 12, including, for example, perpendicular or substantially perpendicular within manufacturing tolerances to the facing surface of the high-speed PCB 20, which can increase the density of data signals.

As shown in FIG. 2, the high-speed PCB 20 uses vias 13 and traces to increase the density of the data signals to allow the data signals to be transported between the high-speed connectors 12 and the IC 11 using the high-speed vias 13 in the power-and-control PCB 10, which minimizes or eliminates the signal integrity (SI) degradation caused by the power-and-control PCB 10. Using the high-speed PCB 20 allows the signals to be closer to the IC 11 than without the high-speed PCB 20 and provides each of the data signals from each of the high-speed connectors 12 with the same or substantially the same within manufacturing tolerances path length through the power-and-control PCB 10. Because the path length of each of the data signals through the power-and-control PCB 10 is the same or substantially the same, the power-and-control PCB 10 causes the same or approximately the same SI degradation to each of the data signals. If the path lengths through the high-speed PCB 20 vary, the high-speed PCB 20 can cause varying degrees of SI degradation to the data signals. The high-speed PCB 20 can also include an opening or a cavity directly underneath where the bypass capacitors are mounted to the power-and-control PCB 10, which provides mechanical clearance for the bypass capacitors. The center of the high-speed PCB 20 can be open in the center to allow for such a cavity.

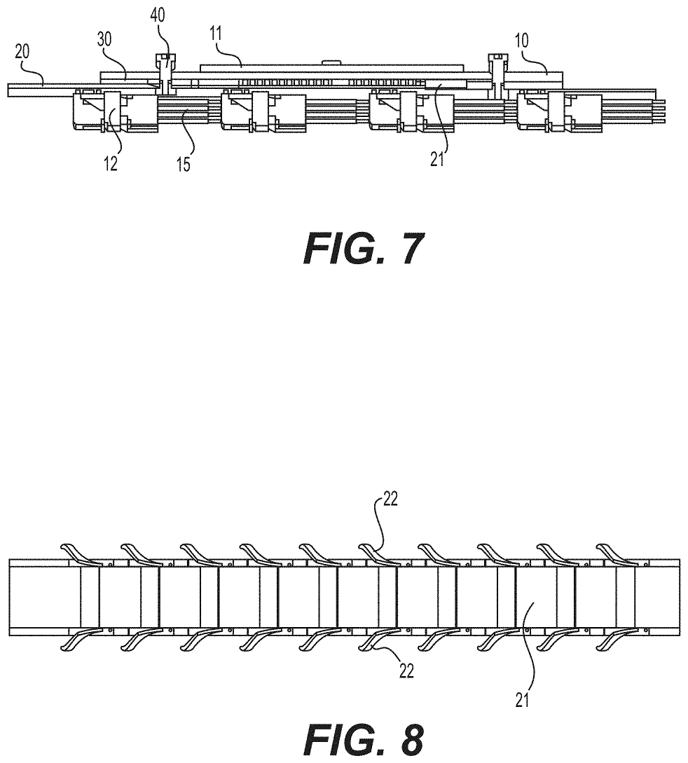

Similar to FIG. 2, FIGS. 3 and 7 show a die package including a power-and-control PCB 10 with an IC 11 mounted on one side. FIGS. 3 and 7 also show a high-speed PCB 20 with high-speed connectors 12 mounted on one side, and high-speed interconnects 21 between the power-and-control PCB 10 and the high-speed PCB 20. FIG. 3 also shows a spacer/stiffener 30 used to maintain the spacing between the power-and-control PCB 10 and the high-speed PCB 20 and to set the compression of the contacts 22 of the high-speed interconnects 21.

The spacer 30 maintains a predetermined spacing between the two PCBs 10, 20 shown in FIG. 3 so that the contacts 22 of the high-speed interconnects 21 are not inelastically deformed when the power-and-control PCB 10 and high-speed PCB 20 are attached together. The spacer 30 also improves mechanical integrity of the entire dual PCB assembly. As shown in FIG. 3, the spacer 30 can define a contiguous rectangular shape that includes the high-speed interconnects 21. The spacer 30 in FIGS. 3 and 7 also includes through holes in which fastening hardware (not shown in FIG. 3) would pass through from an outer surface of one of power-and-control PCB 10 or high-speed PCB 20, through the spacer 30, and to an outer surface of the other of the high-speed PCB 20 or power-and-control PCB 10 to attach the two PCBs 10, 20 and high-speed interconnects 21 together. For example, as shown in FIG. 7, bolts 40 could be used to connect the two PCBs 10, 20 together. The two PCBs 10, 20 can be soft connected, i.e., not permanently connected such that the PCBs 10, 20 can be disconnected without damaging the PCBs 10, 20, or hard connected, i.e., permanently connected such that the PCBs 10, 20 cannot be disconnected without damaging the PCBs 10, 20. Soft connecting allows the two PCBs 10, 20, and related systems, to be manufactured separately.

The two PCBs 10, 20 can be connected together in any suitable manner using any suitable technology, including, for example, interposers of the same or different types, separable connectors, BGA technology, pogo pins. The connector can use press-fit, compression, through hole, or SMT. Any connector that allows for a separable Z-axis connection can be used to connect the power-and-control PCB 10 and the high-speed PCB 20. For example, any suitable RF connector, such as subminiature version A (SMA), subminiature push-on (SMP), etc., can be used.

For example, the high-speed interconnects 21 shown in FIGS. 2 and 3 can preferably be a Z-Ray® high-density array from Samtec, as shown in the cross-sectional view of FIG. 8, or any other suitable compression connector. U.S. Pat. Nos. 7,056,131, 7,371,073, and 7,758,351, the entire contents of each patent are incorporated by reference, disclose examples of connectors that can used for the high-speed interconnects 21.

FIGS. 4 and 5 show top and bottom plan views of one high-speed interconnect 21 shown in FIG. 3. The high-speed interconnects 21 can be a low-profile, high-density one-piece array with compression contacts 22 on two sides as shown in FIG. 8. The compression contacts 22 can be made of beryllium copper (BeCU), but other suitable materials are possible. In alternative configurations, the contacts 22 can be replaced with solder balls on two sides, or the contacts 22 can be replaced with solder balls on only one side, while still using the compression contacts 22 on the other side. As shown in FIGS. 4 and 5, the compression contacts 22 are defined in two arrays, although any number of arrays and size of arrays are possible. In FIGS. 4, 5, and 8, the high-speed interconnects 21 include an optional substrate in which the compression contacts 22 are embedded. It is possible to directly attach contacts to the high-speed PCB 10 without such a substrate, which eliminates the need to have two sets of contacts.

For example, the profile of the high-speed interconnect 21 can be 0.33 mm-4.00 mm in height with a contact pitch of 0.80 mm-1.27 mm and with a performance of at least 15 Gbps and other performances described above. A variety of custom configurations are possible.

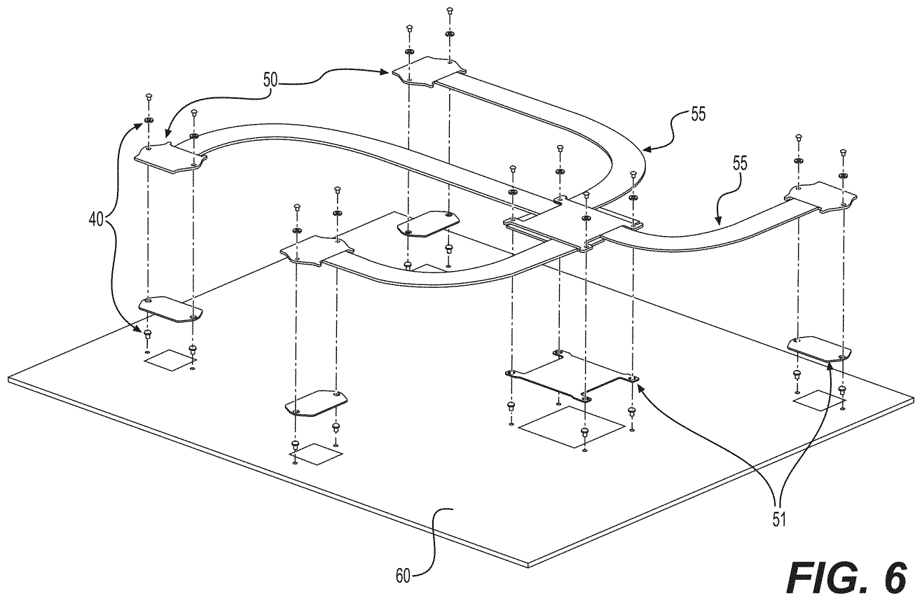

As mentioned above, a PCB architecture using more than two PCBs and multiple high-speed compression interconnects 51 is possible. For example, FIG. 6 shows high-speed compression interconnects 51 on a PCB 60. A cable assembly can include a plurality of power-and-control PCBs 50, each interconnected to a common power-and-control PCB by flexible circuits, coaxial cables or twin axial cables 55. In FIG. 6, dies can be positioned on the power-and-control PCBs 50 and the PCB 60 can be a high speed PCB. Alternatively, the PCBs 50 can be high speed PCBs, and the PCB 60 can be a power-and-control PCB. In FIG. 6, the side of the PCB 60 that is not shown can include five dies or ICs corresponding to the five compression interconnects 51.

The cable assembly can include four flexible circuits, coaxial cable bundles, or twinaxial cable bundles 55 that connect the PCBs 50, with the flexible circuits or cables 55 each connected to one PCB 50 and with all flexible circuits, coaxial cable bundles, or twinaxial cable bundles 55 connected to the same or common center PCB 50. Each of the five PCBs 50 connected together with the flexible circuits, coaxial cable bundles, or twinaxial cable bundles 55 are connected to the one large PCB 60 with the high-speed interconnects 51. Many alternative configurations are possible. As shown in FIG. 6, the flexible circuits, coaxial cable bundles, or twinaxial cable bundles 55 can be directly connected to the PCB 60, or the flexible circuits, coaxial cable bundles, or twinaxial cable bundles 55 can include connectors, such as high-speed connectors 12 shown in FIG. 2, that allow the flexible circuits, coaxial cable bundles, or twinaxial cable bundles 55 to be more easily connected and disconnected to the PCB 60.

The high-speed PCB 20 with the high-speed interconnect 21 can be used in device-under-test (DUT) applications in which the high-speed PCB 20 with the high-speed interconnect 21 can be used as the DUT board to provide connections to the device to be tested.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims. Any elements or description of any embodiment described herein can be mixed with, added to, or subtracted from any other embodiment described herein.

1: A printed circuit board (PCB) assembly comprising:
a first PCB;
a high-speed PCB; and
a high-speed interconnect electrically and physically connecting the first PCB and the high-speed PCB.

2: The PCB assembly of claim 1, wherein the first PCB transports power and control signals.

3: The PCB assembly of claim 1, wherein the first PCB includes high-speed vias that transport high-speed signals between the first PCB and the high-speed PCB.

4: The PCB assembly of claim 3, wherein:
the first PCB includes an integrated circuit (IC); and
the high-speed vias transport the high-speed signals between the IC and the high-speed PCB.

5: The PCB assembly of claim 1, further comprising a die package that includes the first PCB and an integrated circuit (IC).

6: The PCB assembly of claim 1, wherein the high-speed PCB transports high-speed data signals.

7: The PCB assembly of claim 1, further comprising a high-speed connector connected to the high-speed PCB.

8: The PCB assembly of claim 7, wherein the high-speed connector is either a copper connector or an electrical/optical assembly with an optical connector.

9: The PCB assembly of claim 1, wherein the high-speed PCB includes engineered PCB material.

10: The PCB assembly of claim 1, wherein the first PCB includes FR-4.

11: The PCB assembly of claim 1, wherein the high-speed interconnect is a compression interconnect.

12: The PCB assembly of claim 11, wherein the high-speed interconnect includes compression contacts.

13: A high-speed printed circuit board (PCB) assembly comprising:
a high-speed PCB that includes engineered PCB material; and
a high-speed interconnect that is electrically and physically connected to the high-speed PCB and that is mateable with another PCB.

14: The high-speed PCB assembly of claim 13, wherein the high-speed PCB transports high-speed data signals.

15: The high-speed PCB assembly of claim 13, wherein the high-speed PCB includes a high-speed connector.

16: The high-speed PCB assembly of claim 15, wherein the high-speed connector is either a copper connector or an electrical/optical assembly with an optical connector.

17: The high-speed PCB assembly of claim 13, wherein the high-speed interconnect is a compression interconnect.

18: The high-speed PCB assembly of claim 17, wherein the high-speed interconnect includes compression contacts.

19: A transmission apparatus comprising a die package removably connected to a high-speed printed circuit board.

20: The transmission apparatus of claim 19, further comprising a high-speed interconnect positioned between the die package and the high-speed printed circuit board.

21: The transmission apparatus of claim 19, wherein the die package includes an FR-4 substrate.

22-23. (canceled)
